(19) United States
(12) Patent Application Publication
(10) Pub. No.: US 2023/0344418 A1
(43) Pub. Date: Oct. 26, 2023

(54) LEVEL SHIFTER AND INTEGRATED CIRCUIT SYSTEM INCLUDING THE SAME

(71) Applicant: Haechitech Corporation, Cheongju-si (KR)

(72) Inventors: Tae Woo OH, Bucheon-si (KR); Hyung Il KIM, Seoul (KR)

(73) Assignee: Haechitech Corporation, Cheongju-si (KR)

(21) Appl. No.: 18/105,095

(22) Filed: Feb. 2, 2023

(30) Foreign Application Priority Data
Apr. 26, 2022 (KR) 10-2022-0051208

(51) Int. Cl. H03K 19/0185; H03K 3/356; H03K 3/3565

(52) U.S. Cl. CPC H03K 3/356034; H03K 3/3565; H03K 19/018535

(57) ABSTRACT

Disclosed are a circuit and a system which prevent unnecessary power consumption by cutting off static current occurring when a signal is transmitted from an integrated circuit with a low power supply voltage to an integrated circuit with a high power supply voltage.

### CROSS-REFERENCE TO RELATED APPLICATION

The present application claims priority of Korean Patent Application No. 10-2022-0051208 filed on Apr. 26, 2022, the entire contents of which are incorporated herein for all purposes by this reference.

### BACKGROUND OF THE DISCLOSURE

### Field of the Disclosure

The present disclosure relates to a level shifter and an integrated circuit system including the same, and is directed to increasing the reliability of circuit operation by preventing unnecessary static current paths that occur when data is exchanged between a plurality of integrated circuits using different power supply voltages.

### Description of the Related Art

Integrated circuits (ICs) in a system using the multiple ICs often use different power supply voltages. For example, as illustrated in FIG. 1, in case that two ICs (IC1 and IC2) use power supply voltages of V_{DDL} and V_{DDL}, respectively and V_{DDL} is a lower voltage than V_{DDH}, the high voltage of various data or a clock signal CLK output from IC1 becomes V_{DDL}. When the value of V_{DDL} is 1.2 V and the value of V_{DDH} is 1.8 V, direct current may flow at an input terminal of IC2 due to the difference between the values of V_{DDL} and V_{DDH} even though IC1 transmits a high value to IC2. In particular, the disadvantage that a value of V_{DDH} -V_{DDL} approaches a threshold voltage of a CMOS transistor may cause IC2 to continuously consume static current and cause malfunctions. This case mainly occurs when a signal is transmitted from an IC with a low power supply voltage to an IC with a high power supply voltage.

This problem occurs particularly often when IC1 is a host processor and IC2 is a chip for serial data transmission. Moreover, even though the value of the power supply voltage, V_{DDL} of IC1 is 1.2 V, the minimum value thereof set in the specification is usually smaller than 1.2 V, thereby making the problem of static current consumption even more serious.

An appropriate level shifter has been used to prevent this problem, and FIGS. 2 and 3 exemplarily illustrate circuits used in the related art. In these drawings, it should be noted that load transistors constituted by PMOS are represented by Mₚ₁ and M_{P2}, driving transistors constituted by NMOS are represented by M_{N1} and M_{N2}, respectively, and an input signal of the circuit is represented by IN and an inverted input signal through an inverter is represented by INb. FIG. 2 is a view illustrating an example of configuring an input circuit using latch PMOS transistors M_{P1} and M_{P2} as a load. While the circuit illustrated in FIG. 2 has the advantage of preventing the flow of static current, the circuit has the disadvantage of overcoming the voltage collision problem of internal nodes when an input transitions from High to Low. FIG. 3 is a view illustrating an input circuit using current mirror transistors M_{P1} and M_{P2} as a load. While the circuit has a disadvantage of generating the flow of static current, the circuit has the advantage of having no problem of a voltage collision between internal nodes. A more detailed description of an operation of the related art will be omitted.

### SUMMARY OF THE DISCLOSURE

Accordingly, the present disclosure has been made keeping in mind the above problems occurring in the related art, and the present disclosure is intended to provide a circuit and a system including the same, which are capable of preventing unnecessary consumption of static current and malfunctions when a signal is transmitted from an IC with a low power supply voltage to an IC with a high power supply voltage.

The present disclosure may provide a level shifter including: a sensing amplification unit; a transmitting switch unit; a pull-up/pull-down unit; a Schmitt trigger unit; and an inverter chain unit.

The present disclosure may provide a system, which includes a level shifter, the system including: a first integrated circuit configured to use a first power supply voltage; a second integrated circuit configured to use a second power supply voltage, in which the second integrated circuit includes the level shifter including a sensing amplification unit, a pull-up/pull-down unit, a Schmitt trigger unit, and an inverter chain unit.

According to an embodiment of the present disclosure, there is an advantage in that unnecessary consumption of static current may be prevented when a signal is transmitted from an IC with a low power supply voltage to an IC with a high power supply voltage. In addition, according to the embodiment of the present disclosure, there is an advantage in that malfunctions caused by the flow of static current may be prevented.

### BRIEF DESCRIPTION OF THE DRAWINGS

FIG. 1 is a view for schematically explaining a system according to the present disclosure.

FIG. 2 illustrates an embodiment according to the related art.

FIG. 3 illustrates another embodiment according to the related art.

FIG. 4 illustrates a configuration of an embodiment according to the present disclosure.

FIG. 5 illustrates a part of an operation of the configuration of the embodiment according to the present disclosure.

FIG. 6 illustrates a part of a timing diagram according to the present disclosure.

FIG. 7 illustrates another part of the operation of the configuration of the embodiment according to the present disclosure.

FIG. 8 illustrates another part of the timing diagram according to the present disclosure.

### DETAILED DESCRIPTION OF THE DISCLOSURE

Hereinafter, embodiments of the present disclosure will be described in detail with reference to the accompanying drawings so that those with ordinary skill in the art to which the present disclosure pertains may easily carry out the embodiments. The same reference numerals refer to the same members among the reference numerals indicated in the respective drawings.

In the description of the present disclosure, the specific descriptions of publicly known related technologies will be omitted when it is determined that the specific descriptions may obscure the subject matter of the present disclosure.

The terms such as “first” and “second” may be used to describe various constituent elements, but the constituent elements should not be limited by the terms, and these terms are used only to distinguish one constituent element from another constituent element.

As schematically illustrated in FIG. 4, a level shifter 10 according to the present disclosure may be configured to include a sensing amplification unit 110, a transmitting switch unit 120, a pull-up/pull-down unit 130, a Schmitt trigger unit 140, and an inverter chain unit 150, and an input signal and an output signal are represented by IN and OUT, respectively. As is well known, according to the present disclosure, even though values of the input signal IN swing between 0 and V_{DDL}, values of the output signal OUT are intended to swing between 0 and V_{DDH}.

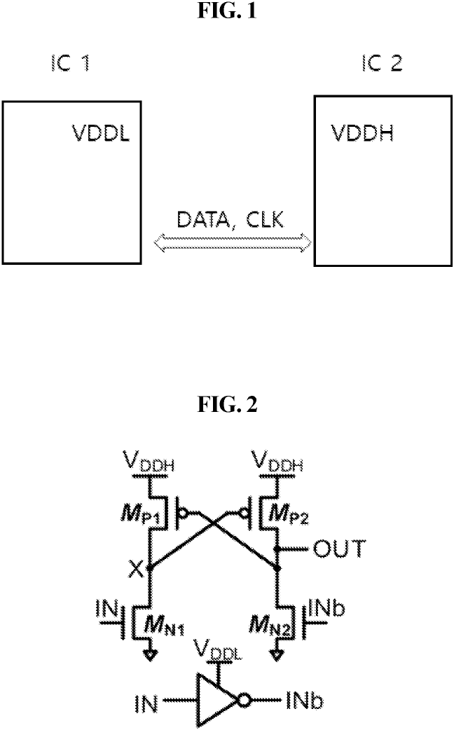

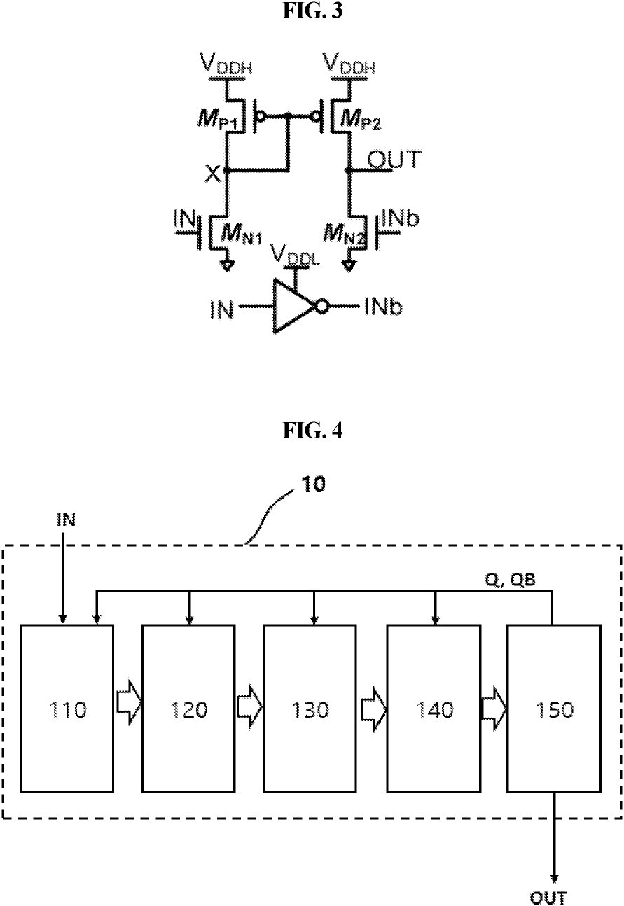

As widely known, the level shifter 10 according to the present disclosure is included in an integrated circuit (IC) using a higher power supply voltage among a plurality of integrated circuits (ICs). For example, referring to FIG. 1, more particularly, the level shifter 10 according to the present disclosure may be included in an IC2.

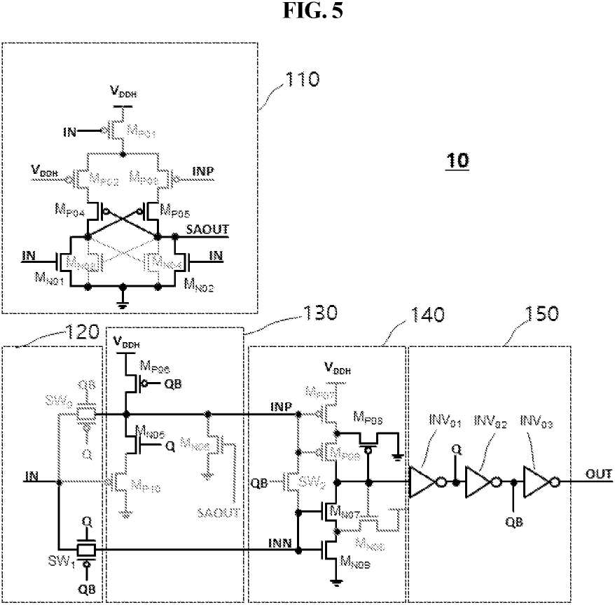

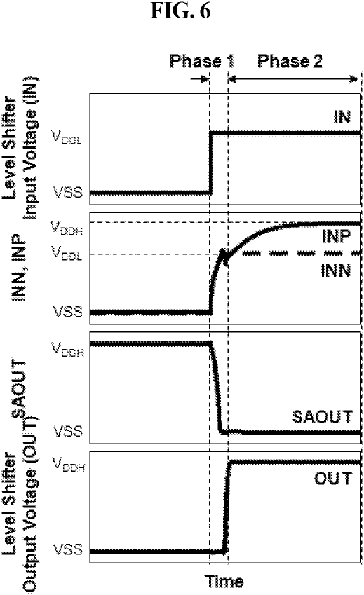

Hereinafter, a configuration and operation of each partial circuit will be described. First, a case in which the input signal IN transmitted from an IC1 to the level shifter 10 included in the IC2 transitions from LOW to HIGH will be described with reference to FIG. 5. In FIG. 5, elements that are turned on are represented in dark colors and elements that are turned off are represented in light colors to assist in easier understanding.

When the input signal IN transitions from LOW to HIGH, M_{P01}, which is a switch element of the sensing amplification unit 110, is turned off, and a power supply voltage V_{DDH} supplied to the sensing amplification unit 110 is cut off. Then, NMOS transistors M_{N01} and M_{N02}, which are driving elements, are turned on to discharge a voltage of an output node SAOUT of the sensing amplification unit 110 to the ground. For reference, since a voltage value of HIGH of the input signal IN is V_{DDL}, as described in the above problem, the switch element M_{P01} is not perfectly turned off, and thus there is always a possibility that some leakage current flows. Even in this case, the leakage current flow of the sensing amplification unit 110 is completely cut off by an operation in which the load elements M_{P02}and M_{P03} are turned off. In this case, since gate voltages of some PMOS load transistors M_{P04} and M_{P05} change to LOW, the PMOS load transistors M_{P04} and M_{P05} are turned on, and the voltage of the output node SAOUT of the sensing amplification unit 110 is latched and maintained with being discharged to the ground.

The sensing amplification unit 110 is configured to have driving elements M_{N01} and M_{N02}, latch elements M_{N03}, M_{N04,} M_{P04}, and M_{P05}, switch element M_{P01} and load elements M_{P02} and M_{P03}.

When the input signal IN is LOW, that is, just before the input signal IN transitions from LOW to HIGH, switches SW₀ and SW₁ of the transmitting switch unit 120 are in turned-on and turned-off states, respectively, and a switch SW₂ of the Schmitt trigger unit 140 is in a turned-on state. Since the LOW state of the input signal IN, that is, a ground voltage Vss, is transmitted to two inputs INN and INP of the Schmitt trigger unit 130 in advance by the operation of these switches. Therefore, an output of the Schmitt trigger unit 140 is in a HIGH state, and two outputs Q and QB of the inverter chain unit 150 are in LOW and HIGH states, respectively. Of course, accordingly, the output signal OUT of the level shifter 10 maintains a LOW state.

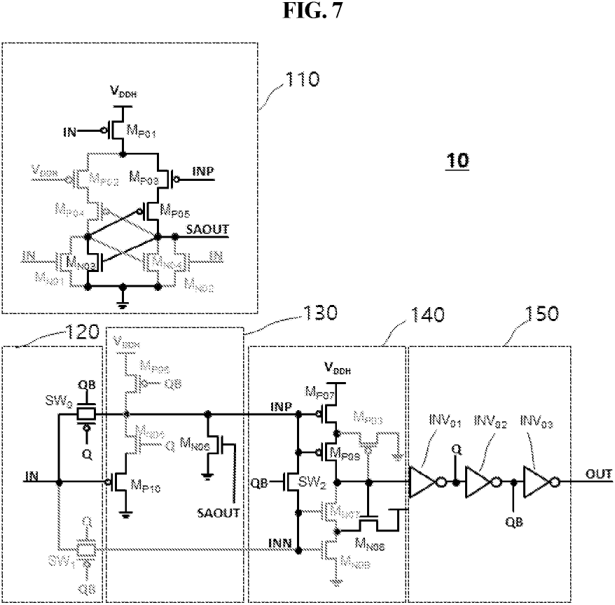

For reference, a drawing just before the transition of the input signal IN from LOW to HIGH may be easily understood by partially referring to the turned-on and turned-off states illustrated in FIG. 7.

Since the switches SW₀ and SW₁ of the transmitting switch unit 120 will maintain turned-on and turned-off states, respectively, immediately after the input signal IN transitions from LOW to HIGH, the two input signals INN and INP of the Schmitt trigger unit 140 start to be charged toward the V_{DDL} value, which is the HIGH value of the input signal IN through the switches SW₀ and SW₂, and M_{P07} and M_{P09} elements positioned on a charging path of the Schmitt trigger unit 140 are turned off and cut off the charging path according to the charging of the input signal INP.

Then, according to the charging of the input signal INN, M_{N07} and M_{N09} elements positioned in a discharging path of the Schmitt trigger unit 140 are turned on, and the output of the Schmitt trigger unit 140 starts to be discharged. Each output of the inverter chain unit 150 sequentially transitions from the previous state, the Q and QB signals change to HIGH and LOW, respectively, and the output OUT of the level shifter 10 becomes HIGH.

The Q and QB signals of the inverter chain unit 150 are fed back, so that the states of the switches SW₀ and SW₁ of the transmitting switch unit 120 are changed to turned-off and turned-on states, respectively. As an M_{P06} element in a pull-up path of the pull-up/pull-down unit 130 is turned on, the INP, which is an input node of the Schmitt trigger unit 140, continues to be charged, in this case, with the V_{DDH} value transmitted from the pull-up/pull-down unit 130. The switch SW₂ of the Schmitt trigger unit 140 is cut off by the QB signal fed back, and the INP node and the INN node are separated.

It should be noted that the input node INP of the Schmitt trigger unit 140 is charged with the V_{DDH} value, whereas another input node INN of the Schmitt trigger unit 140 is charged with the V_{DDL} value, which is transmitted from the input signal IN of the level shifter 10.

Next, a case in which the input signal IN transmitted from the IC1 to the level shifter 10 included in the IC2 transitions from HIGH to LOW will be described with reference to FIG. 7. In FIG. 7, elements that are turned on are represented in dark colors and elements that are turned off are represented in light colors to assist in easier understanding.

The switch element M_{P01} of the sensing amplification unit 110 directly connected to the input signal IN is turned on immediately after the input signal IN transitions from HIGH to LOW, and the power supply voltage V_{DDH} starts to be supplied to the sensing amplification unit 110. Then, the two driving transistors M_{N01} and M_{N02} are turned off, and a PMOS element M_{P10} of the pull-up/pull-down unit 130 is turned on.

The input node INN of the Schmitt trigger unit 140 connected to the input signal IN through the switch SW₁ of the transmitting switch unit 120 also starts to be discharged. Another input node INP of the Schmitt trigger unit 140 is slowly discharged from V_{DDH} through discharging paths of an M_{N05} element maintaining the previous turned-on state and the newly turned-on M_{P10} element in the pull-up/pull-down unit 130.

Therefore, the M_{P03} element of the sensing amplification unit 110 is turned on and starts to charge the SAOUT node, which is an output node. Thus, the charging of the SAOUT node is accelerated by the positive feedback effect of the four transistors M_{P04}, M_{P05}, M_{N03}, and M_{N04} that form a latch structure in the sensing amplification unit 110.

As a voltage of the SAOUT node changes to V_{DDH}, an M_{N06} element of the pull-up/pull-down unit 130 is turned on, and the INP node is discharged. The above process is further accelerated to turn on the charging transistors M_{P07} and M_{P09} of the Schmitt trigger unit 140, and thus the output of the Schmitt trigger unit 140 is rapidly charged to V_{DDH} and the state thereof is changed. Each output of the inverter chain unit 150 sequentially transitions from the previous state, the Q and QB signals change to LOW and HIGH, respectively, and the output OUT of the level shifter 10 becomes LOW.

As the Q and QB signals of the inverter chain unit 150 are fed back, the states of the switches SW₀ and SW₁ of the transmitting switch unit 120 are changed to the turned-on and turned-off states, respectively, and the INN node of the Schmitt trigger unit 140, which started to be discharged according to the input signal IN, completes the discharging to the ground voltage Vss according to the INP as the switch SW₂ is turned on.

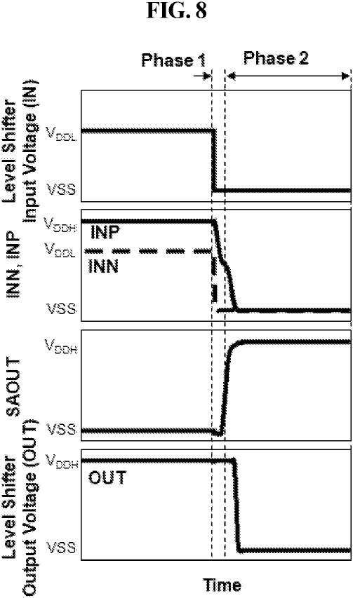

For the summary of the above operations, a timing diagram for the input signal IN, the two inputs INN and INP of the Schmitt trigger unit 130, the output SAOUT of the sensing amplification unit, and the output OUT of the level shifter 10 is illustrated in FIG. 8.

In the operation of each circuit constituting the level shifter according to the present disclosure, there is no power loss due to the static current since all the static current paths from the power supply voltage V_{DDH} to the ground are also cut off in this case.

For the summary of the above operations, a timing diagram for the two inputs INN and INP of the Schmitt trigger unit 130, the output SAOUT of the sensing amplification unit, and the output OUT of the level shifter 10 is illustrated in FIG. 6. For reference, the parts represented by Phase1 and Phase2 in the timing diagram mean a transition period and a stabilized period after the transition is completed, respectively.

Therefore, in the operation of each circuit constituting the level shifter 10 according to the present disclosure, there is no power loss due to the static current since all the static current paths from the power supply voltage V_{DDH} to the ground are cut off.

When a signal is transmitted from the integrated circuit IC1 with a low power supply voltage to the integrated circuit IC2 with a high power supply voltage, the unnecessary consumption of static current may be prevented according to the system in which the level shifter 10 according to the present disclosure is included as an input circuit of the integrated circuit IC2 with a high power supply voltage. In addition, there is an advantage in that malfunction caused by the flow of static current may be prevented.

While the present disclosure has been described with reference to the embodiments illustrated in the drawings, the embodiments are for illustrative purposes only, and those skilled in the art to which the present disclosure pertains will understand that various modifications of the embodiment and any other embodiment equivalent thereto are available. Accordingly, the true technical protection scope of the present disclosure should be determined by the technical spirit of the appended claims.

What is claimed is:

1. A level shifter comprising:
a sensing amplification unit;
a transmitting switch unit;
a pull-up/pull-down unit;
a Schmitt trigger unit; and
an inverter chain unit.

2. The level shifter of claim 1, wherein an output of the inverter chain unit is fed back to inputs of the sensing amplification unit, the pull-up/pull-down unit, and the Schmitt trigger unit.

3. The level shifter of claim 1, wherein only one of two or more switches in the transmitting switch unit is turned on according to a change in an input signal.

4. The level shifter of claim 1, wherein the sensing amplification unit is configured to have driving elements, latch elements, current source element, and load element.

5. A system, which comprises a level shifter, the system comprising:
a first integrated circuit configured to use a first power supply voltage;
a second integrated circuit configured to use a second power supply voltage,
wherein the second integrated circuit comprises the level shifter comprising a sensing amplification unit, a pull-up/pull-down unit, a Schmitt trigger unit, and an inverter chain unit.

6. The system of claim 5, wherein an output of the inverter chain unit is fed back to inputs of the sensing amplification unit, the pull-up/pull-down unit, and the Schmitt trigger unit.

7. The system of claim 5, wherein only one of two or more switches in the transmitting switch unit is turned on according to a change in an input signal.

8. The system of claim 5, wherein the sensing amplification unit is configured to have driving elements, latch elements, current source element, and load element.

9. The system of claim 5, wherein the second power supply voltage is higher than the first power supply voltage.
